(19) United States
(12) Patent Application Publication
(10) Pub. No.: US 2008/0006919 A1
(43) Pub. Date: Jan. 10, 2008

(54) Flip chip package and method of fabricating the same

(75) Inventor: Chi-hyun In, Hwaseong-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 11/790,177

(22) Filed: Apr. 24, 2007

(30) Foreign Application Priority Data
Jul. 4, 2006 (KR) 10-2006-0062402

(51) Int. Cl. H01L 23/06

(52) U.S. Cl. 257/684; 257/E23.191

(57) ABSTRACT

A flip chip package may include a semiconductor substrate, the semiconductor substrate having a metal interconnection formed in the semiconductor substrate. A passivation layer formed over the semiconductor substrate exposing at least a portion of a metal interconnection formed in the semiconductor substrate. A conductive pad may be formed over the passivation layer and being connected to the metal interconnection. A barrier layer may be formed over the conductive pad and a portion of the passivation layer. A bump structure may be formed over the barrier layer.

### PRIORITY STATEMENT

This U.S. non-provisional application claims the benefit of priority to Korean Patent Application No. 10-2006-0062402, filed on Jul. 4, 2006, in the Korean Intellectual Property Office (KIPO), the disclosure of which is incorporated herein in its entirety by reference.

### BACKGROUND

1. Field

Example embodiments relate to a semiconductor package and a method of fabricating the same, for example, a flip chip package and a method of fabricating the same.

2. Description of the Related Art

Semiconductor packages have been developed that may ensure operating reliability while reducing the size of the package. Semiconductor packages were developed from a surface mountable lead frame type, which is mostly used in a micro-chip scale package, and is being developed for flip chip packages. A flip chip package is a semiconductor package formed by directly bonding a conductive pad of a semiconductor chip to a bonding pad of a board, using a conductive bump, for example, a solder ball, a gold bump, and the like. As opposed to a semiconductor package that is fabricated by a wire bonding method using a gold wire, a flip chip package may be more applicable to a lead frame pattern having a micro pitch. Additionally, the flip chip package may be employed in more highly-integrated circuit structures because of its lighter weight and thinner, flatter form. Furthermore, the flip chip package may improve integration density of the semiconductor package and may incur lower fabrication costs because the electro-paths of the flip chip package are shortened, which may improve speed and power.

A flip chip package may include a conductive bump that connects a conductive pad of a semiconductor chip to a conductive pad of a board, for example, a printed circuit board or a glass substrate. The conductive bump may be a solder bump, a gold bump, an electroless bump, and the like. The conductive bump may be almost the same size as the conductive pad of the semiconductor chip.

A conventional method of forming a gold bump may include forming a barrier layer on the resultant surface of a semiconductor substrate having a conductive pad. A resist pattern may be formed on the barrier layer such that the upper surface and the sidewall of the conductive pad are exposed. The gold bump may be formed on the barrier layer of the exposed conductive pad using a plating method. After the resist pattern is removed, the barrier layer may be removed by a wet etch method by using the gold bump as a mask.

However, if the barrier layer is removed by a wet etch method, the barrier layer is removed isotropically. Thus, the barrier layer may be undercut beneath the gold bump.

As such, due to the undercut of the barrier layer, the resultant structure of the gold bump and the barrier layer may have an unstable inverse pyramid shape, wherein the upper portion of the pyramid shape is wider than the lower portion of the pyramid shape.

If the unstable gold bump is bonded to an integrated substrate (or glass) by applying pressure in a subsequent process, the gold bump may break and/or a bond may be formed wherein the conductive bump has a deformed shape. As a result, the electrical and physical reliability of the flip chip package may be deteriorated.

### SUMMARY

Example embodiments provide a flip chip package capable of reducing or preventing the undercut of a barrier layer.

Example embodiments provide a method of fabricating a flip chip package that may prevent assembly failures in a semiconductor package by reducing or preventing the undercut of a barrier layer.

In an example embodiment, a flip chip package may include a semiconductor substrate. A passivation layer may be formed over the semiconductor substrate exposing at least a portion of a metal interconnection formed in the semiconductor substrate. A conductive pad may be formed on the passivation layer and being connected to the metal interconnection. A barrier layer may be formed over the conductive pad and a portion of the passivation layer. A bump structure may be formed over the barrier layer.

According to an example embodiment, the bump structure may include a preliminary bump formed on the surface of the barrier layer and a main bump formed on the preliminary bump.

According to an example embodiment, the bump structure may include a protrusion formed on at least one lower edge portion that extends beyond an outer sidewall of the bump structure.

According to an example embodiment, the barrier layer may include an adhesive layer formed over the upper surface and sidewalls of the conductive pad and a portion of the semiconductor substrate. A seed layer may be formed on the adhesive layer.

In an example embodiment, a flip chip package may include a semiconductor substrate. A passivation layer may be formed over the semiconductor substrate exposing at least a portion of a metal interconnection formed in the semiconductor substrate. A conductive pad may be formed on the passivation layer, the conductive layer being connected to the metal interconnection. A barrier layer may be formed over the conductive pad and a portion of the passivation layer. A bump structure may be formed over the barrier layer, the bump structure protruding at both lower edge portions.

In an example embodiment, a method of fabricating a flip chip package may include forming a conductive pad over a substrate; forming a barrier layer over the conductive pad; forming a bump structure over the barrier layer, the bump structure having a lower portion and an upper portion, a width of the lower portion being greater than a width of the upper portion; and removing a portion of the barrier layer using the bump structure as a mask.

According to an example embodiment, forming the bump structure may include forming a mask pattern on the barrier layer, the mask pattern having an opening exposing a portion of the barrier layer, at least a portion of the exposed portion of the barrier layer being formed over the conductive pad; forming a preliminary bump on the exposed portion of the barrier layer; shielding at least one edge portion of the preliminary bump; forming a main bump on the exposed portion of the preliminary bump; and removing the mask pattern.

According to an example embodiment, forming the barrier layer may include forming an adhesive layer forming an adhesive layer over the conductive pad and the passivation layer; and forming a seed layer on the adhesive layer.

### BRIEF DESCRIPTION OF THE DRAWINGS

Example embodiments will be described with reference to the accompanying drawings.

FIGS. 1 through 4 are sectional views illustrating a method of fabricating a flip chip package having a bump structure according to example embodiments.

FIG. 5A is a sectional view illustrating an example embodiment of a flip chip having a bump structure.

FIG. 5B is a sectional view illustrating another example embodiment of a flip chip having a bump structure.

### DESCRIPTION OF EXAMPLE EMBODIMENTS

Example embodiments will now be described more fully hereinafter with reference to the accompanying drawings. Example embodiments may, however, be embodied in many different forms and should not be construed as being limited to the example embodiments set forth herein. Rather, these example embodiments are provided so that this disclosure will be thorough, and will fully convey the scope to those skilled in the art. In the drawings, the thickness of the layers and regions are exaggerated for clarity. Like numbers refer to like elements throughout the specification.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of the example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

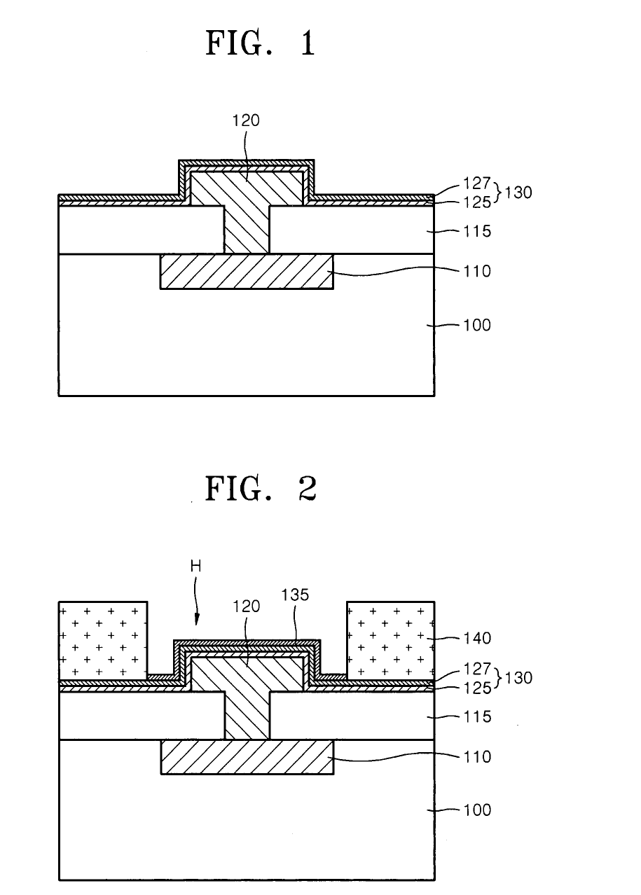

FIGS. 1 through 5 are sectional views illustrating a method of fabricating a flip chip package having a bump structure according to an example embodiment.

Referring to FIG. 1, a passivation layer 115 may be formed on a semiconductor substrate 100 having a metal interconnection 110, for example, a metal pad. The semiconductor substrate 100 may include circuit devices (not shown). Electrodes of the circuit devices may be connected to the metal interconnection 110. The passivation layer 115 may be etched such that a predetermined portion (or alternatively, a desired portion) of the metal interconnection 110 is exposed.

A conductive pad 120 may be formed on the passivation layer 115. The conductive pad 120 may contact the exposed portion of the metal interconnection 110. For example, the conductive pad 120 may include an aluminium layer or an aluminium alloy layer having conductive properties. The aluminium layer or aluminium alloy layer may be patterned to form the conductive pad 120 contacting the metal interconnection 110.

A barrier layer 130 may be formed on the conductive pad 120 and the passivation layer 115. The barrier layer 130 may improve the adhesive property between the passivation layer 115 and a conductive bump, for example, a gold bump, that may subsequently be formed, and may function as a seed for the conductive bump. The barrier layer 130 may include an adhesive layer 125 and a seed layer 127, which may be sequentially stacked. For example, the adhesive layer 125 may be composed of titanium (Ti), and the seed layer 127 may be composed of gold (Au).

Referring to FIG. 2, a resist pattern 140 may be formed having an opening H exposing at least a portion the barrier layer 130 formed over the upper surface and the sidewalls of the conductive pad 120. The opening H of the resist pattern 140 may have a diameter greater than the width or diameter of the conductive pad 120.

A preliminary bump 135 (e.g., a preliminary bump layer) may be formed over the seed layer 127 of the barrier layer 130. For example, the preliminary bump 135 may be composed of gold (Au) and may have a thickness of about 1000 to 3000 Å. The preliminary bump 135 may be formed using a plating method. The preliminary bump 135 may reduce or prevent undercutting of the barrier layer 130 during a subsequent wet etch process of the barrier layer 130.

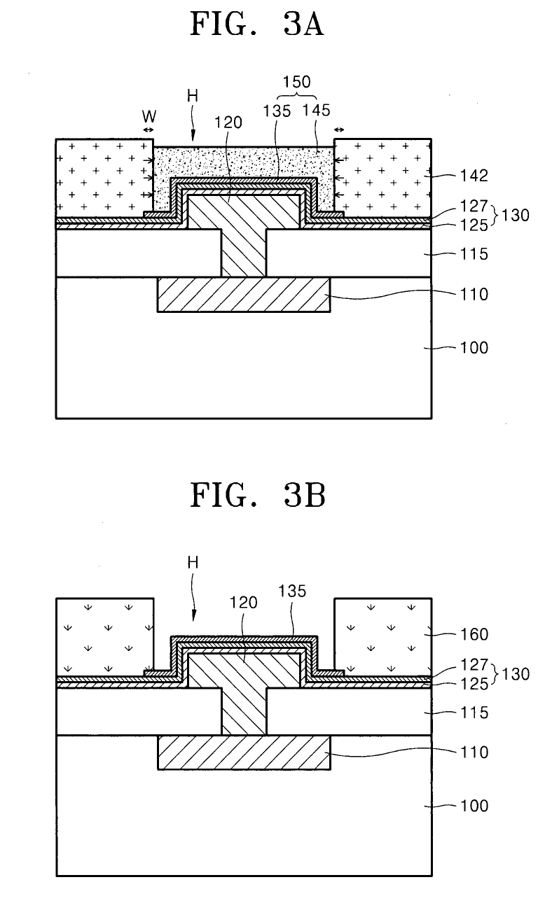

Referring to FIG. 3A, the diameter or width of the opening H formed in the resist pattern 140 may be reduced by extending the sidewalls of the resist pattern 140 by a predetermined width (or alternatively, a desired width) W. The width W of the extension of the resist pattern 140 may be about 1/10 to 1/100 of the entire width of the preliminary bump 135. For example, the sidewalls of the resist pattern 140 may be extended by the width W of 2000 to 3000 Å. The resulting extended resist pattern 142 may not cover the sidewalls of the conductive pad 120.

In an example embodiment, the width W of the resist pattern 140 may be extended using a reflow method. The reflow method may be performed by thermally treating the resist pattern 140 at a predetermined temperature (or alternatively, a desired temperature), for example, a temperature in a range of about 100° C. to 200° C. In another example embodiment, as illustrated in FIG. 3B, the resist pattern 140 may be removed, and a new resist pattern 160 may be formed having an opening H with a diameter or width smaller than the diameter or width of the opening in the resist pattern 140.

Referring to again to FIG. 3A, a main bump 145 may be formed on the exposed preliminary bump 135. As shown, a diameter or width of the main bump 145 is less than a diameter or width of the preliminary bump 135 such that portions of the preliminary bump 135 are not covered by the main bump 145. For example, the main bump 145 may be composed of gold and may be formed using a plating method. The main bump 145 and the preliminary bump 135 may form a bump structure 150.

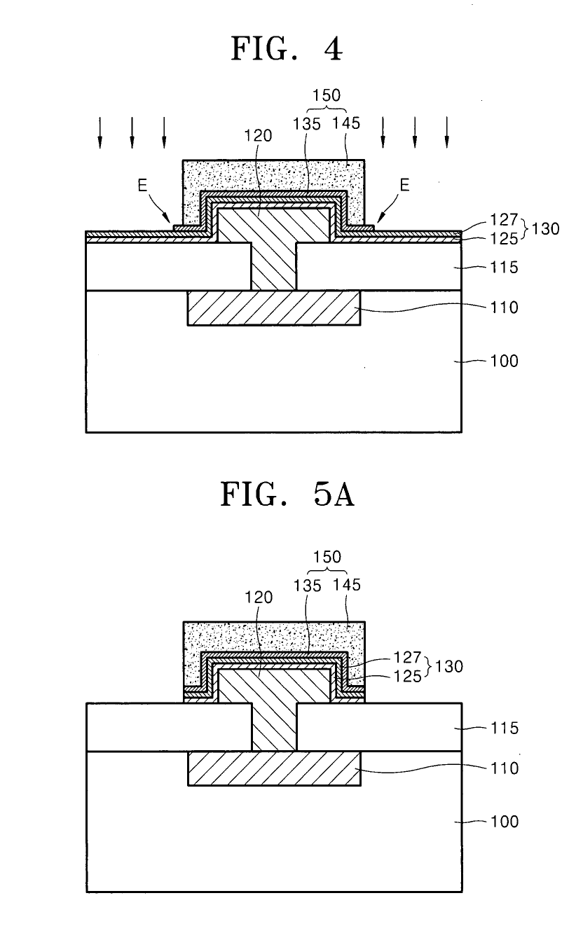

Referring to FIG. 4, the resist pattern 142 may be removed to expose the bump structure 150. A lower portion of the bump structure 150 may be wider than an upper portion of the bump structure 150. The lower portion E of the bump structure 150 may have a step shape due to the expansion of the width W of the resist pattern 140. For example, the preliminary bump 135 may protrude beyond the sidewall of the main bump 145, and the preliminary bump 135 and the main bump 145 may have a step height difference. Namely, the height of the main bump 145 may be greater than the height of the preliminary bump 135.

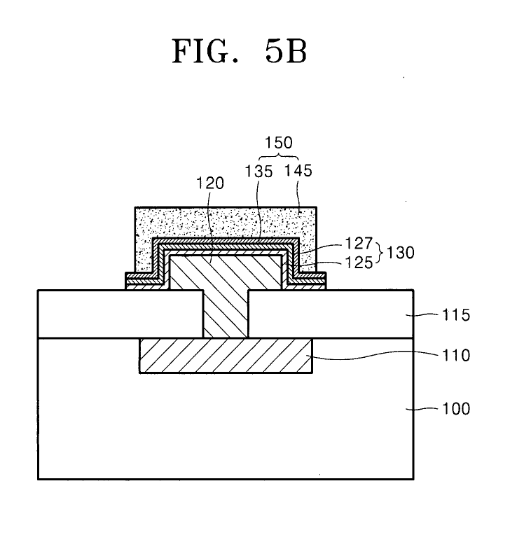

Referring to FIG. 5A, the barrier layer 130 and the preliminary bump 135 may be wet-etched using the bump structure 150 as a mask. For example, the barrier layer 130 and the preliminary bump 135 may be isotropically etched by the wet-etch method. However, the portion of the preliminary bump 135 that protrudes beyond the sidewall of the main bump 145 may function as a buffer during the process of removing the barrier layer 130, thereby reducing or preventing the undercutting of the barrier layer 130, and more particularly, the undercutting of the gold seed layer 127.

If undercutting of the barrier layer 130 is reduced or prevented, the bump structure 150 may be formed having a more stable shape. For example, according to an example embodiment, a lower portion of the bump structure 150 may be as wide (FIG. 5A) as an upper portion of the bump structure 150. According to another example embodiment, a lower portion of the bump structure may be wider than an upper portion of the bump structure 150 (FIG. 5B). The more stable shape may reduce or prevent breakage or deformation of the bump structure 150 during a subsequent package formation process.

In an example embodiment described above, a resist pattern may be used as a mask to define a bump formation space; however, example embodiments are not limited thereto. For example, any fluid material capable of preventing gold plating may be used as a mask to define the bump formation space.

According to an example embodiment, a protrusion may be formed at a lower edge portion E (see FIG. 4) of a bump structure 150 by an expansion process of the width of a resist pattern 140 (see FIG. 3A). The protrusions may extend beyond an outer sidewall of a main bump 145. If the bump structure 150 is rounded in shape, the protrusion may be formed circumferentially around the bump structure 150. If the bump structure is a multi-sided shape (e.g., rectangular), a protrusion may be formed on at least one side of the bump structure 150. The protrusions of the bump structure 150 may function as buffers during the process of removing a barrier layer 130, thereby reducing or preventing the undercutting of the barrier layer 130.

According to example embodiments, because the undercutting of the barrier layer 130 may be reduced or prevented, the bump structure 150 may be bonded to a substrate without breaking or deforming during sequential package formation processes. Furthermore, assembly efficiency of the flip chip package may be increased.

While example embodiments have been particularly shown and described, it will be understood by those of ordinary skill in the art that various changes in form and detail may be made therein without departing from the spirit and scope of the invention.

What is claimed is:

1. A flip chip package comprising:
a semiconductor substrate;
a passivation layer formed over the semiconductor substrate exposing at least a portion of a metal interconnection formed in the semiconductor substrate;
a conductive pad formed over the passivation layer and being connected to the metal interconnection;
a barrier layer formed over the conductive pad and a portion of the passivation layer; and
a bump structure formed over the barrier layer.

2. The flip chip package of claim 1, wherein the bump structure includes:
a preliminary bump formed on the surface of the barrier layer; and
a main bump formed on the preliminary bump.

3. The flip chip package of claim 2, wherein the preliminary bump has a thickness of about 1000 to 3000 Å.

4. The flip chip package of claim 2, wherein the main bump has a thickness greater than the thickness of the preliminary bump.

5. The flip chip package of claim 2, wherein at least one of the preliminary bump and the main bump includes gold (Au).

6. The flip chip package of claim 1, wherein the bump structure includes a protrusion formed on at least one lower edge portion that extends beyond an upper, outer sidewall of the bump structure.

7. The flip chip package of claim 6, wherein the bump structure comprises:
a preliminary bump formed on the surface of the barrier layer; and
a main bump formed on the preliminary bump,
wherein the preliminary bump extends beyond the sidewalls of the main bump to form the protrusion.

8. The flip chip package of claim 6, wherein the protrusion is formed circumferentially around the bump structure.

9. The flip chip package of claim 1, wherein the barrier layer comprises:
an adhesive layer formed over the conductive pad and the portion of the passivation layer; and
a seed layer formed on the adhesive layer.

10. The flip chip package of claim 9, wherein the adhesive layer includes titanium (Ti).

11. A flip chip package comprising:
a semiconductor substrate;
a passivation layer formed over the semiconductor substrate exposing at least a portion of a metal interconnection formed in the semiconductor substrate;
a conductive pad formed over the passivation layer and being connected to the metal interconnection;
a barrier layer formed over the conductive pad and a portion of the passivation layer; and
a bump structure formed over the barrier layer, the bump structure protruding at both lower edge portions.

12. A method of fabricating a flip chip package comprising:
forming a conductive pad over a substrate;
forming a barrier layer over the conductive pad;
forming a bump structure over the barrier layer, the bump structure having a lower portion and an upper portion, a width of the lower portion being greater than a width of the upper portion; and
removing a portion of the barrier layer using the bump structure as a mask.

13. The method of claim 12, wherein the forming of the bump structure comprises:
forming a mask pattern on the barrier layer, the mask pattern having an opening exposing a portion of the barrier layer, at least a portion of the exposed portion of the barrier layer being formed over the conductive pad;
forming a preliminary bump on the exposed portion of the barrier layer;
shielding at least one edge portion of the preliminary bump;
forming a main bump on the exposed portion of the preliminary bump; and
removing the mask pattern.

14. The method of claim 13, wherein shielding the edge portion of the preliminary bump includes performing a reflow process on the mask pattern to extend the width of the sidewalls of the mask pattern.

15. The method of claim 13, wherein shielding the edge portion of the preliminary bump comprises removing the mask pattern; and
forming a new mask pattern shielding the edge portion of the preliminary bump.

16. The method of claim 13, wherein shielding the edge portion of the preliminary bump includes shielding an edge portion having a width of about 1/10 to 1/100 of an entire width of the bump structure.

17. The method of claim 13, wherein shielding the edge portion of the preliminary bump includes shielding an edge portion having a width of about 2000 to 3000 Å.

18. The method of claim 13, wherein forming the preliminary bump includes forming the preliminary bump to a thickness of about 1000 to 3000 Å.

19. The method of claim 13, wherein the main bump is formed having a thickness greater than the thickness of the preliminary bump.

20. The method of claim 13, wherein at least one of the preliminary bump and the main bump includes gold (Au).

21. The method of claim 12, wherein forming the barrier layer includes:
forming an adhesive layer over the conductive pad and the passivation layer; and
forming a seed layer over the adhesive layer.

22. The method of claim 21, wherein the adhesive layer includes titanium (Ti).

23. The method of claim 21, wherein the seed layer includes gold (Au).

24. The method of claim 12, further comprising:
forming a passivation layer over the substrate,
wherein a metal interconnect is formed in the substrate, at least a portion of a metal interconnection is exposed by the passivation layer and connected to the conductive pad.
